(19) United States
(12) Patent Application Publication
(10) Pub. No.: US 2007/0145521 A1
(43) Pub. Date: Jun. 28, 2007

(54) SEMICONDUCTOR DEVICE AND METHOD OF MANUFACTURING THE SAME

(76) Inventor: Eun Jong Shin, Seoul (KR)

Correspondence Address: SHERR & NOURSE, PLLC, 620 HERNDON PARKWAY, SUITE 200, HERNDON, VA, 20170, US

(21) Appl. No.: 11/609,889

(22) Filed: Dec. 12, 2006

(30) Foreign Application Priority Data
Dec. 28, 2005 (KR) 10-2005-0132351

(51) Int. Cl. H01L 29/00

(52) U.S. Cl. 257/510

(57) ABSTRACT

embodiments relate to a semiconductor device that may include a continuously formed pad oxide layer and a field oxide layer. The device may include a semiconductor substrate having a trench, an insulating material formed in the trench, a pad oxide layer formed at the active region of the semiconductor substrate and a field oxide layer formed on the insulating material.

The present application claims priority under 35 U.S.C. 119 and 35 U.S.C. 365 to Korean Patent Application No. 10-2005-0132351 (filed on Dec. 28, 2005), which is hereby incorporated by reference in its entirety.

### BACKGROUND

As semiconductor devices have become more highly integrated, a critical dimension of a gate has gradually become smaller. As a width of a transistor becomes narrower, it may be beneficial to form a trench having a depth greater than a depth of a source-drain junction of the transistor to electrically isolate devices.

Semiconductor devices may be electrically isolated through a local oxidation of silicon (LOCOS) process, or through a shallow trench isolation (STI) process. In a LOCOS process, a silicon substrate may be recessed to grow an oxide layer, while in an STI process a silicon substrate may be vertically etched and then the etched portion may be filled with an insulating material.

FIGS. 1-4 are example diagrams illustrating a related art method of manufacturing a semiconductor device.

Referring to FIG. 1, semiconductor substrate 10 may be heated to form oxide layer 11 at an upper portion thereof. Nitride layer 12 may be formed as an etch stop on oxide layer 11.

Photoresist pattern 13 may be formed on nitride layer 12. A trench to isolate active regions between semiconductor devices may be formed, for example by using photoresist pattern 13 as a mask.

Referring to FIG. 2, nitride layer 12, oxide layer 11, and semiconductor substrate 10 may be etched using photoresist pattern 13 as an etching mask. Trench 14 may thus be formed within semiconductor substrate 10.

Referring to FIG. 3, photoresist pattern 13 may be removed, for example through an ashing process. Insulating material 15, for example such as an oxide material, may be deposited within trench 14.

The insulating material formed on nitride layer 12 may be removed, for example by a chemical mechanical polishing (CMP) process using nitride layer 12 as an etch stop layer.

Nitride layer 12 and oxide layer 11 formed on semiconductor substrate 10 may be removed and may form isolation layer 16 as illustrated in FIG. 4.

When the isolation layer is formed as described above, a height difference may be generated between a top portion of the isolation layer and an active region of the semiconductor device. For example, a portion of isolation layer may extrude beyond the active region of the semiconductor device.

In addition, at an edge portion between the active region and a neighboring isolation layer, a divot may be generated. The divot may be generated when removing the oxide layer formed at an inner layer of a trench of the active region. Since the divot may be filled with polysilicon when forming a gate electrode, a leakage current might be generated when operating the semiconductor device.

Further, during the etching process to remove the nitride layer and the oxide layer to expose the active region exclusive of the trench region, the isolation layer may be etched together with the nitride layer and the oxide layer.

Due to this phenomenon, impurities may remain in a gap of an isolation layer while subsequent gate oxidation and polysilicon etching processes are performed, and certain characteristics of the semiconductor device may be detrimentally affected.

In addition, since an upper corner of the isolation layer and a corner portion of contiguous active region may have a relatively steep profile, an electric field may concentrate at a gap between the active region and the trench or on a surface of the trench. This may cause a partial electric discharge.

Such a partial electric discharge may cause partial corrosion of the device. Moreover, when an energy density of the electric discharge increases locally, corrosion may become more severe, and may cause certain device characteristics to deteriorate due to a short of the semiconductor device.

Further, since an upper corner portion of a trench may commonly be formed with an angular profile, an insulating material may not be sufficiently filled into the trench during a gap fill process for filling the trench with the insulating material. Accordingly, a possibility of a leakage current may increase.

For a highly integrated semiconductor device having a narrow isolation length between devices and having a small distance between neighboring devices, a leakage current may have a detrimental effect upon neighboring devices, and a semiconductor device may therefore fail to operate properly.

### SUMMARY

Embodiments relate to a semiconductor device that may have no gap at a corner portion where a trench isolation region and an active region meet by forming a field oxide layer that may cover the active region and the trench isolation region.

In embodiments, a semiconductor device may include a semiconductor substrate including a trench to define active regions, an insulating material formed within the trench, a pad oxide layer formed on the active region of the semiconductor substrate and a field oxide layer formed on the insulating material. In embodiments, the pad oxide layer and the field oxide layer may be connected continuously and/or contiguously.

In embodiments, a method of manufacturing a semiconductor device may include successively forming a pad oxide layer and a pad nitride layer on the semiconductor substrate, implementing a first etching process to etch the pad oxide layer and the pad nitride layer, implementing a second etching process to etch the semiconductor substrate to a predetermined depth, forming an insulating material in the semiconductor substrate, planarizing the insulating material and forming a field oxide layer on the insulating material by growing the pad oxide layer.

### BRIEF DESCRIPTION OF THE DRAWINGS

FIGS. 1-4 are example cross-sectional diagrams illustrating a related art method of manufacturing a semiconductor device; and

FIGS. 5-11 are example cross-sectional diagrams illustrating a method of manufacturing a semiconductor device according to embodiments.

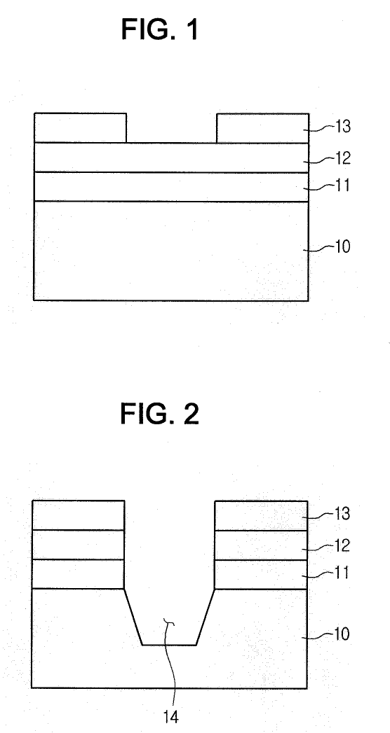

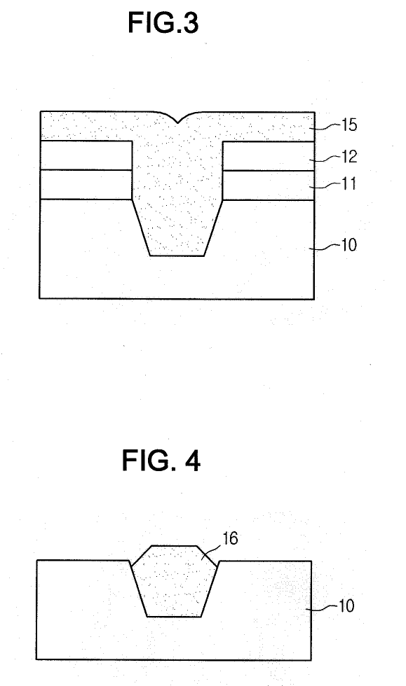

### DETAILED DESCRIPTION OF EMBODIMENTS

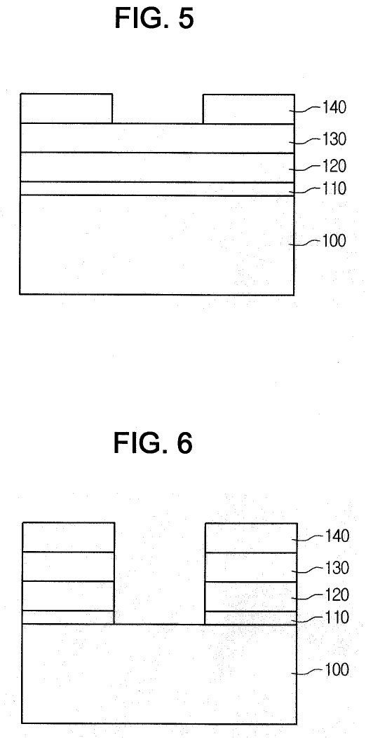

Referring to FIG. 5, to form a trench for defining an active region, semiconductor substrate 100 may be heated under an oxygen atmosphere at a temperature of approximately 760° C.˜860° C. and pad oxide layer 110 may be formed thereon.

Pad nitride layer 120 may be formed as an etch stop on pad oxide layer 110, for example using a low-pressure CVD (LPCVD) method.

Insulating layer 130 may be formed on pad nitride layer 120, for example using a low-pressure CVD method. In embodiments, insulating layer 130 may be formed using tetraethyl orthosilicate (TEOS) or other oxide or nitride material.

Photoresist may be coated on insulating layer 130 to form photoresist pattern 140.

Referring to FIG. 6, a first etching process may be carried out to etch insulating layer 130, pad nitride layer 120, and pad oxide layer 110. A portion of semiconductor substrate 100 may thus be exposed. In embodiments, the first etching process may be accomplished by a reactive ion etching (RIE) method and may use photoresist pattern 140 as a mask.

In embodiments, the reactive ion etching may be implemented by using at least one of a gas having an anisotropic etching characteristic such as CF₄ gas, CHF₃ gas, O₂ gas, or a mixture thereof.

Photoresist pattern 140 may be removed, for example through an ashing process.

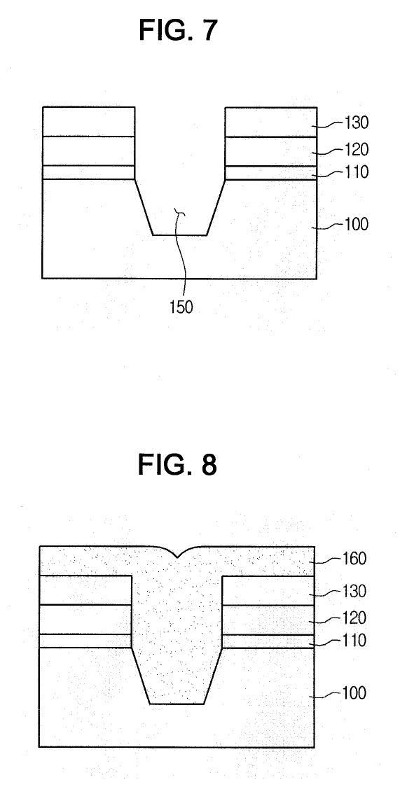

Referring to FIG. 7, a second etching process of etching semiconductor substrate 100 may be implemented, for example by using insulating layer 130 as a mask.

In embodiments, the second etching process may be accomplished by reactive ion etching using insulating layer 130 as a mask. In embodiments, semiconductor substrate 100 may be etched to a depth of approximately 3000 Å˜4000 Å through the reactive ion etching.

Trench 150 may thus be formed within semiconductor substrate 100.

Since insulating layer 130 may be used as a mask to etch semiconductor substrate 100, trench 150 may be formed to a deeper position (i.e. a greater depth) than a depth of the source/drain junction of a transistor.

In embodiments, since an upper corner portion of trench 150 may have a very sharp profile, an electric field concentration effect may be induced. For this reason, a dry oxidation process may be implemented.

The dry oxidation process may be carried out by heating semiconductor substrate 100 to approximately 900˜1250° C. Pure oxygen may be used as an oxidation gas to form an oxide layer at trench 150 of semiconductor substrate 100.

Referring to FIG. 8, insulating material 160, for example such as USG, may be deposited, and may bury trench 150. This may be accomplished using a high density plasma (HDP) process.

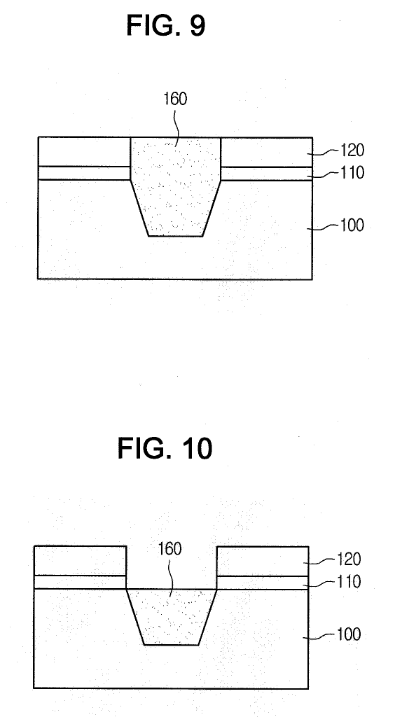

Referring to FIG. 9, a CMP process may be carried out to planarize insulating material 160. In embodiments, pad nitride layer 120 may be used as an etch stop layer during the CMP process.

In embodiments, the planarization process of insulating material 160 may be implemented in other ways as well. For example, photoresist may be coated on semiconductor substrate 100 on which insulating material 160 may be deposited. The photoresist may be patterned, for example, to expose the active region exclusive of the trench region. Insulating material 160 may then be selectively dry etched.

Referring to FIG. 10, an upper portion of insulating material 160 may be etched, for example by using pad nitride layer 120 as a mask.

In embodiments, the etching of insulating material 160 may be carried out through a reactive ion etching process. Moreover the etching may be carried out until a surface of insulating material 160 is lower than a height of pad oxide layer 110.

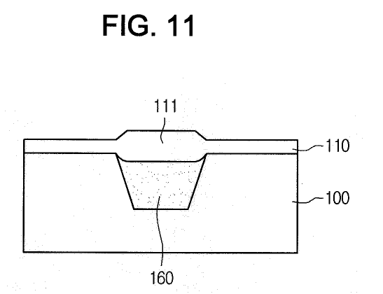

Referring to FIG. 11, a wet etching process using a solution such as H₃PO₄ solution may be implemented to remove pad nitride layer 120.

An oxidation process may be applied to pad oxide layer 110 to thermally oxidize and to form field oxide layer 111 on the insulating material of the trench region.

Field oxide layer 111 may thus be formed on insulating material 160.

Field oxide layer 111 may be formed by growing pad oxide layer 110 using a thermal oxidation process on pad oxide layer 110. As the pad oxide layer formed at left and right side of insulating material 160 grows, field oxide layer 111 may be formed having a shape illustrated in FIG. 11.

Pad oxide layer 110 may grow to a bottom side portion of the oxide layer of the active region as well as in a vertical direction to give a “bird's beak” shaped oxide layer.

Field oxide layer 111 may be formed by the thermal growing of pad oxide layer 110 and may be continuously connected to pad oxide layer 110. For example, pad oxide layer 110 may be contiguous with field oxide layer 111, having no gaps in therebetween.

According to embodiments, field oxide layer 111 may serve as an isolation layer and field oxide layer 111 may cause there to be no gap at a boundary of the active region and the isolation layer.

In embodiments, this result may be accomplished because field oxide layer 111 may be formed to cover a corner of an active region and insulating material 160.

In embodiments, since field oxide layer 111 may be formed on insulating material 160 and pad oxide layer 110 may be formed at the active region, a subsequent and separate formation of an oxide layer to implant ions into the active region may not be necessary.

In embodiments, the etching of insulating material 160 may be separately implemented as a first etching process and a second etching process, and an upper portion of insulating material 160 may be etched by the first etching process, the width at the mouth portion of the trench may be widened to facilitate subsequent processes.

It will be apparent to those skilled in the art that various modifications and variations can be made to embodiments. Thus, it is intended that embodiments cover modifications and variations thereof within the scope of the appended claims. It is also understood that when a layer is referred to as being “on” or “over” another layer or substrate, it can be directly on the other layer or substrate, or intervening layers may also be present.

What is claimed is:

1. A device comprising:
a semiconductor substrate including a trench;
an insulating material formed in the trench;
a pad oxide layer formed on an active region of the semiconductor substrate; and
a field oxide layer formed on the insulating material,
wherein the pad oxide layer and the field oxide layer are contiguously formed.

2. The device of claim 1, wherein the field oxide layer protrudes higher than a height of the pad oxide layer by a prescribed thickness.

3. The device of claim 1, wherein a surface of the insulating material is located at a position lower than a height of the pad oxide layer.

4. The device of claim 1, wherein the trench defines active regions.

5. A method comprising:
forming a pad oxide layer on a semiconductor substrate;
forming a trench in the semiconductor substrate by etching the pad oxide layer and the semiconductor substrate;
forming an insulating material in the trench; and
forming a field oxide layer on the insulating material by growing the pad oxide layer.

6. The method of claim 5, further comprising:
sequentially forming the pad oxide layer and a pad nitride layer on the semiconductor substrate;
performing a first etching process to etch the pad oxide layer and the pad nitride layer;
performing a second etching process to etch the semiconductor substrate to a prescribed depth to form the trench; and
planarizing the insulating material.

7. The method of claim 6, further comprising forming an insulating layer on the pad nitride layer after forming the pad nitride layer on the semiconductor substrate.

8. The method of claim 6, further comprising etching a portion of the insulating material by using the pad nitride layer as an etching mask after planarizing the insulating material.

9. The method of claim 8, further comprising removing the pad nitride layer by performing a wet etching using H₃PO₄ solution after etching the portion of the insulating material.

10. The method of claim 6, wherein at least one of the first etching process and the second etching process comprises a reactive ion etching process.

11. The method of claim 6, wherein the second etching process is implemented until the semiconductor substrate is etched to a depth of approximately 3000 Å˜4000 Å.

12. The method of claim 11, wherein the second etching process comprises reactive ion etching.

13. The method of claim 5, wherein forming the field oxide layer comprises thermally oxidizing the pad oxide layer.

14. The method of claim 5, wherein forming the insulating material in the trench comprises depositing USG material using a high density plasma (HDP) process.

15. The method of claim 5, wherein the pad oxide layer and the field oxide layer are contiguously formed.

16. The method of claim 5, wherein the field oxide layer is formed to have a first height higher than a second height of the pad oxide layer by a prescribed thickness.
